(19) United States
(12) Patent Application Publication
(10) Pub. No.: US 2007/0210402 A1
(43) Pub. Date: Sep. 13, 2007

(54) Varactor

(76) Inventors: Yu-Chia Chen, Taipei City (TW); Hua-Chou Tseng, Hsinchu (TW); Cheng-Chou Hung, Jhubei City (TW)

Correspondence Address: J.C. Patents, Inc., Suite 250, 4 Venture, Irvine, CA, 92618, US

(21) Appl. No.: 11/370,965

(22) Filed: Mar. 7, 2006

(51) Int. Cl. H01L 29/93

(52) U.S. Cl. 257/480

(57) ABSTRACT

A varactor including a substrate, a P well disposed in the substrate, a gate structure disposed over the substrate, a p+ source disposed in the substrate at one side of the gate structure, a p+ drain disposed in the substrate at the other side of the gate structure, and a deep N well disposed in the substrate under the P well is provided. The gate oxide of the varactor is thicker so as to reduce the probability of the current leakage occurrence.

### BACKGROUND OF THE INVENTION

1. Field of the Invention

The present invention relates to a varactor, and more particularly, to a varactor that can reduce the possibility of current leakage occurrence.

2. Description of the Related Art

In a typical communication system, the information signal (e.g. the TV program signal) is tuned and put on a high-frequency carrier, such that the signal can be easily transmitted on the carrier. Multiple information signals can be transmitted at the same time by using the characteristic of different frequency carrying a different carrier signal. Therefore, a voltage controlled oscillator (VCO) is commonly utilized in the receiver of the communication system to separate the information signal from the carrier. Here, the VCO comprises an LC circuit that is composed of a varactor and an inductor. By using the characteristic in which the capacitance of the varactor is varied with the voltage modulation, the oscillation frequency of the VCO is changed accordingly.

The commonly seen varactor includes the MOS (Metal-Oxide-Semiconductor) varactor mainly with an MOS structure and the junction varactor that is formed by interleavedly disposing a p-doped region and an n-doped region. Wherein, in the circuit design of the MOS varactor, one terminal of the source and drain of the MOS transistor is electrically connected to the substrate, and the other terminal is solely used as a gate, so as to form the MOS varactor.

FIG. 1 is a cross-sectional view of a conventional varactor. Referring to FIG. 1, the conventional varactor 100 comprises a substrate 110, a P well 120, a gate oxide 130, a gate 140, an n⁺ source and drain 150, and a spacer 160. However, when the size of the MOS device continuously reduces along with the fabricating process development, the thickness of the gate oxide 130 becomes thinner. Accordingly, the possibility of current leakage occurrence is increased, which deteriorates the device's reliability.

### SUMMARY OF THE INVENTION

Therefore, it is an object of the present invention to provide a varactor. The thickness of the gate oxide in the varactor is thicker than that of the gate oxide of the same size conventional varactor, such that the current leakage problem is avoided.

It is another object of the present invention to provide a varactor that can reduce the possibility of current leakage occurrence.

The present invention provides a varactor. The varactor comprises a substrate, a P well disposed in the substrate, a gate structure disposed over the substrate, a p⁺ source disposed in the substrate at one side of the gate structure, a p⁺ drain disposed in the substrate at the other side of the gate structure, and a deep N well disposed in the substrate under the P well.

In accordance with an embodiment of the present invention, the varactor further comprises a p-sub disposed under the deep N well.

In accordance with an embodiment of the present invention, the varactor further comprises a spacer that is disposed on both sides of the gate structure, and the spacer is made of a material such as silicon nitride.

In accordance with an embodiment of the present invention, the gate structure comprises a gate oxide and a gate that is disposed above the gate oxide. Wherein, the gate is made of a material such as doped polysilicon, and the gate oxide is made of a material such as silicon oxide.

The present invention provides a varactor. The varactor comprises a silicon layer, a P well disposed in the silicon layer, a gate structure disposed over the silicon layer, a p⁺ source disposed in the silicon layer at one side of the gate structure, and a p⁺ drain disposed in the silicon layer at the other side of the gate structure.

In accordance with an embodiment of the present invention, the varactor further comprises an insulating layer disposed under the silicon layer. In addition, the varactor further comprises a high resistance material layer disposed under the insulating layer.

In accordance with an embodiment of the present invention, the varactor further comprises an aluminum oxide layer disposed under the silicon layer.

In accordance with an embodiment of the present invention, the varactor further comprises a spacer that is disposed on both sides of the gate structure, and the spacer is made of a material such as silicon nitride.

In accordance with an embodiment of the present invention, the gate structure comprises a gate oxide and a gate that is disposed above the gate oxide. Wherein, the gate is made of a material such as doped polysilicon, and the gate oxide is made of a material such as silicon oxide.

The p⁺ ion doped source and drain are used in the varactor of the present invention, thus the thickness of the gate oxide is increased, the possibility of current leakage occurrence is reduced, and the electricity and reliability of the device are both improved.

### BRIEF DESCRIPTION OF THE DRAWINGS

The accompanying drawings are included to provide a further understanding of the invention, and are incorporated in and constitute a portion of this specification. The drawings illustrate embodiments of the invention, and together with the description, serve to explain the principles of the invention.

FIG. 1 is a cross-sectional view of a conventional varactor.

FIG. 2 is a cross-sectional view illustrating a structure of a varactor according to an embodiment of the present invention.

FIG. 3 is a cross-sectional view illustrating a structure of a varactor according to another embodiment of the present invention.

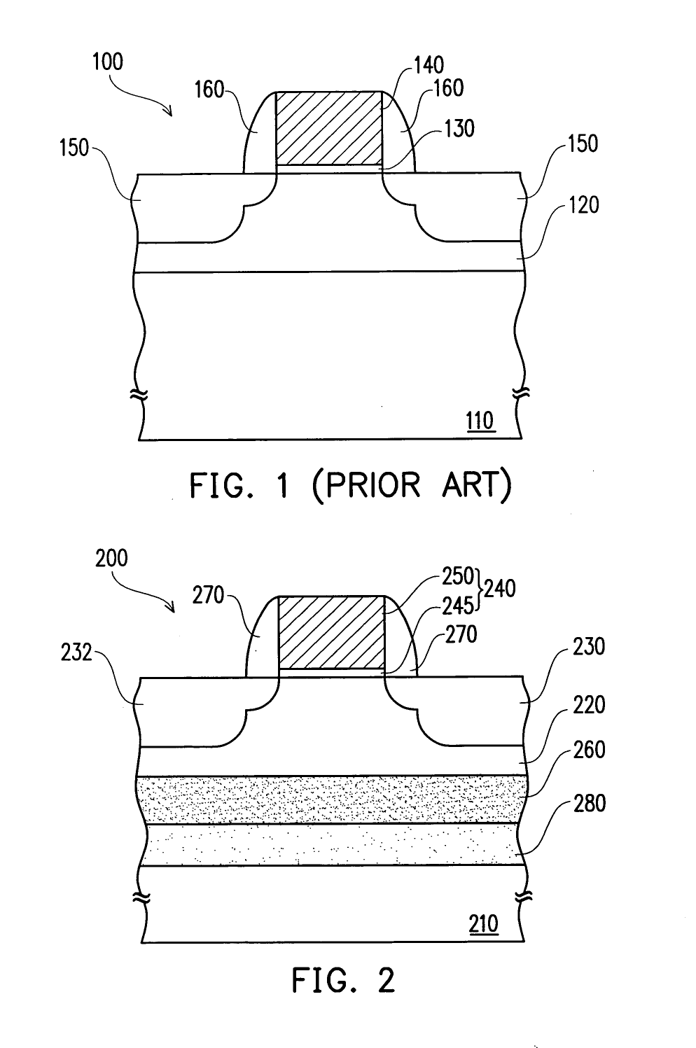

### DESCRIPTION OF THE PREFERRED EMBODIMENTS

FIG. 2 is a cross-sectional view illustrating a structure of a varactor according to an embodiment of the present invention.

Referring to FIG. 2, the varactor 200 comprises a substrate 210, a P well 220 disposed in the substrate 210, a gate structure 240 disposed over the substrate 210, a p+ source 230 disposed in the substrate 210 at one side of the gate structure 240, a p+ drain 232 disposed in the substrate 210 at the other side of the gate structure 240, a deep N well 260 disposed in the substrate 210 under the P well, and a spacer 270 disposed on both sides of the gate structure 240. Wherein, the gate structure 240 comprises a gate oxide 245 and a gate 250 disposed above the gate oxide 245.

Referring to FIG. 2, the substrate 210 is made of silicon wafer or other appropriate material. The gate 250 is made of doped polysilicon or other appropriate material. The gate oxide 245 is made of silicon oxide or other appropriate material. The spacer 270 is made of silicon nitride or other appropriate material.

In an embodiment, a p-sub 280 is further disposed under the deep N well 260. Wherein, the p-sub 280, the deep N well 260, and the P well 220 together constitute a three-well structure in the substrate 210 of the present embodiment. The three-well structure protects the devices deposited thereon from generating an inverse bias on the junction between the deep N well and the P well, which otherwise generates the interferences on the periphery of the N well.

In the varactor 200 of the present embodiment, the n⁺ doped source and drain in the NMOS can be replaced with the p⁺ doped source and drain to form a PMOS having the p⁺ source 230 and the p⁺ drain 232 as shown in FIG. 2, and still have the P well 220 remained in the substrate 210. In general, the thickness of the gate oxide in the PMOS structure is thicker than that of the NMOS structure. Accordingly, the possibility of current leakage occurrence of the PMOS varactor 200 provided by the present invention is reduced, which further improves the device's reliability.

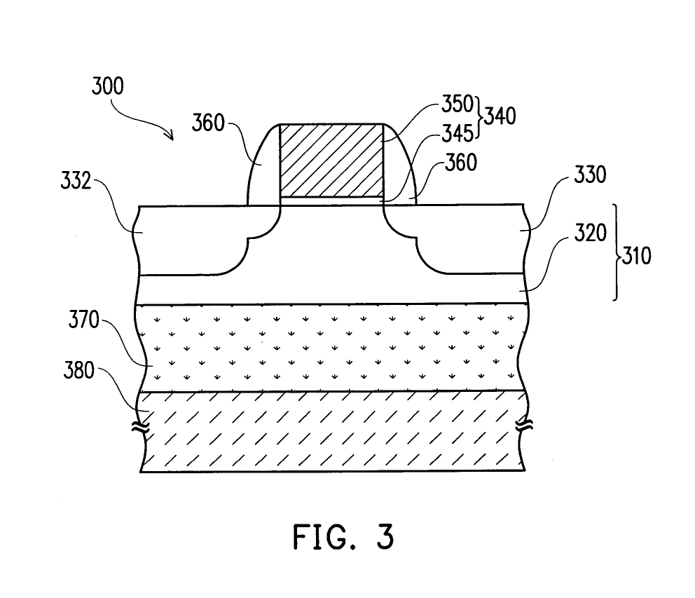

FIG. 3 is a cross-sectional view illustrating a structure of a varactor according to another embodiment of the present invention.

Referring to FIG. 3, the varactor 300 comprises a silicon layer 310, a P well 320 disposed in the silicon layer 310, a gate structure 340 disposed over the silicon layer 310, a p+ source 330 disposed in the silicon layer 310 at one side of the gate structure 340, a p+ drain 332 disposed in the silicon layer 310 at the other side of the gate structure 340, and a spacer 360 disposed on both sides of the gate structure 340. Wherein, the gate structure 340 comprises a gate oxide 345 and a gate 350 disposed above the gate oxide 345.

Referring to FIG. 3, the silicon layer 310 is made of silicon epitaxial wafer or other appropriate material. The gate 350 is made of doped polysilicon or other appropriate material. The gate oxide 345 is made of silicon oxide or other appropriate material. The spacer 360 is made of silicon nitride or other appropriate material.

In an embodiment, as shown in FIG. 3, the silicon layer 310 is disposed above the insulating layer 370, and the insulating layer 370 is disposed above the high resistance material layer 380. Wherein, the insulating layer 370 and the silicon layer 310 disposed thereon together constitute a Silicon On Insulator (SOI) structure. The SOI structure can protect the devices disposed thereon and reduces the parasitic capacitor in the device, such that the purpose of providing a high speed circuit is achieved.

In another embodiment, the silicon layer 310 may be disposed on the aluminum oxide (not shown), such that the aluminum oxide and the silicon layer 310 disposed thereon together constitute a Silicon On Sapphire (SOS) structure. Comparing with the SOI structure mentioned above, such SOS structure can reduce the electricity consumption of the circuit formed on the substrate, and the circuit is not easily damaged by the electrostatic discharge (ESD) during the fabricating process.

Similarly, in the varactor 300 of the present embodiment, the n⁺ doped source and drain in the NMOS are replaced with the p⁺ doped source and drain to form a PMOS having the p⁺ source 330 and the p⁺ drain 332 as shown in FIG. 3, and the P well 320 in the silicon layer 310 is still being used. In general, the thickness of the gate oxide in the PMOS structure is thicker than that of the NMOS structure. Accordingly, the possibility of current leakage occurrence of the PMOS varactor 300 provided by the present invention is reduced, which further improves the device's reliability.

In summary, the thickness of the gate oxide in the varactor is thicker than that of the conventional varactor. Accordingly, the possibility of current leakage occurrence is reduced, and the device's reliability is further improved.

Although the invention has been described with reference to a particular embodiment thereof, it will be apparent to one of the ordinary skills in the art that modifications to the described embodiment may be made without departing from the spirit of the invention. Accordingly, the scope of the invention will be defined by the attached claims not by the above detailed description.

What is claimed is:

1. A varactor, comprising:
a substrate;
a P well disposed in the substrate;
a gate structure disposed above the substrate;
a p⁺ source disposed in the substrate at one side of the gate structure;
a p⁺ drain disposed in the substrate at the other side of the gate structure; and
a deep N well disposed in the substrate under the P well.

2. The varactor of claim 1, further comprising a p-sub that is disposed under the deep N-well.

3. The varactor of claim 1, further comprising a spacer disposed on both sides of the gate structure.

4. The varactor of claim 3, wherein a material of the spacer comprises silicon nitride.

5. The varactor of claim 1, wherein the gate structure comprises a gate oxide and a gate disposed above the gate oxide.

6. The varactor of claim 5, wherein a material of the gate comprises doped polysilicon.

7. The varactor of claim 5, wherein a material of the gate oxide comprises silicon oxide.

8. A varactor, comprising:
a silicon layer;
a P well disposed in the silicon layer;
a gate structure disposed above the silicon layer;
a p⁺ source disposed in the silicon layer at one side of the gate structure; and
a p⁺ drain disposed in the silicon layer at the other side of the gate structure.

9. The varactor of claim 8, further comprising an insulating layer disposed under the silicon layer.

10. The varactor of claim 9, further comprising a high resistance material layer disposed under the insulating layer.

11. The varactor of claim 8, further comprising an aluminum oxide layer disposed under the silicon layer.

12. The varactor of claim 8, further comprising a spacer disposed on both sides of the gate structure.

13. The varactor of claim 12, wherein a material of the spacer comprises silicon nitride.

14. The varactor of claim 8, wherein the gate structure comprises a gate oxide and a gate disposed above the gate oxide.

15. The varactor of claim 14, wherein a material of the gate comprises doped polysilicon.

16. The varactor of claim 14, wherein a material of the gate oxide comprises silicon oxide.
